(19) United States
(12) Patent Application Publication
(10) Pub. No.: US 2025/0236205 A1
(43) Pub. Date: Jul. 24, 2025

(54) ELECTRICAL CIRCUIT FOR A VEHICLE

(71) Applicant: VITESCO TECHNOLOGIES GMBH, Regensburg (DE)

(72) Inventors: Yannick LEROY, Toulouse (FR); Karim BOUKHRIS, Toulouse (FR)

(21) Appl. No.: 18/699,140

(22) PCT Filed: Dec. 9, 2022
(86) PCT No.: PCT/EP2022/085210

§ 371 Date: Apr. 5, 2024

(30) Foreign Application Priority Data
Dec. 21, 2021 (FR) 2114069

(51) Int. Cl. B60L 58/10; H01M 10/42; H02J 7/02; H02M 1/00; H02M 1/42

(52) U.S. Cl. CPC B60L 58/10; H01M 10/425; H02J 7/02; H02M 1/0054; H02M 1/4233; H01M 2220/20

(57) ABSTRACT

The invention relates to an electronic circuit (21) for a motor vehicle, comprising a first branch (B1) comprising a first switch (T1) and at least a second switch (T2), which are connected in parallel between a high point (PH) and a first midpoint (PM1), the first branch (B1) comprising a third switch (T3) and at least a fourth switch (T4), which are connected in parallel between a low point (PB) and the first midpoint (PM1).

### TECHNICAL FIELD

The invention relates to the field of motor vehicles or hybrid vehicles, and more precisely to an electronic circuit for a motor vehicle and to the method for controlling said circuit.

### PRIOR ART

In a known manner, an electric or hybrid vehicle comprises an electric machine and a battery able to supply electrical energy in order to supply power to electrical equipment installed in the vehicle or external to the vehicle, and the electric machine of the vehicle.

The vehicle also comprises an on-board charger, better known as an OBC, which is connected to the battery, on the one hand, and to an electric power supply network, on the other hand. In this case the charger allows the AC voltage supplied by the network to be converted into DC voltage in order to recharge the battery.

In a known manner, an on-board charger comprises a power factor correction circuit, known as a PFC (acronym of power factor corrector), a DC-DC converter, as it is commonly referred to by a person skilled in the art, and a microcontroller able to control the power factor correction circuit.

By way of example, in the case where the battery is being charged, the power factor correction circuit is the element of the on-board charger that is able to convert the AC voltage, supplied by an electrical network external to the vehicle, into a DC voltage. More precisely, the power factor correction circuit has to comprise three parallel branches when the AC voltage to be converted is three-phase. Each branch comprises two transistors that are connected to one another on one phase of the AC voltage.

While being used, each switch is controlled so as to switch, and therefore to open or close. However, when the opening or closing frequency of the switches is high, each switch undergoes “switching” losses that, when repeated and uncontrolled, may heat the switch and greatly reduce its service life.

A solution is therefore required in order to at least partly overcome these disadvantages.

### SUMMARY OF THE INVENTION

To this end, the invention relates to an electronic circuit for a motor vehicle, comprising a first branch comprising a first switch and at least a second switch, which are connected in parallel between a high point and a first midpoint, the first branch comprising a third switch and at least a fourth switch, which are connected in parallel between a low point and the first midpoint.

The circuit as described therefore allows, during use thereof, the switching losses to be distributed between the plurality of switches in parallel and not to just one switch. Therefore, each switch connected in parallel undergoes fewer thermal losses, and therefore ages less rapidly and has a longer service life.

Preferably, the circuit comprises a second branch comprising a fifth switch and at least a sixth switch, which are connected in parallel between the high point and a second midpoint, the second branch comprising a seventh switch and at least an eighth switch, which are connected in parallel between the low point and the second midpoint.

More preferably, the circuit comprises a third branch comprising a ninth switch and at least a tenth switch, which are connected in parallel between the high point and a third midpoint, the third branch comprising an eleventh switch and at least a twelfth switch, which are connected in parallel between the low point and the third midpoint, the third midpoint being electrically connected to the third connection terminal of the electrical network.

Therefore, the circuit may be used to convert a single-phase or three-phase voltage.

More preferably, each switch is a transistor. Transistors are conventional electronic components in this type of circuit.

Advantageously, each switch is a transistor, in particular a MOSFET, SiC MOSFET, IGBT (insulated-gate bipolar transistor) or bipolar transistor, or else a GaN (gallium nitride) field-effect transistor.

Advantageously, the vehicle comprises at least one supply battery, the circuit being intended to be connected to an electrical network, on the one hand, which is external to the vehicle and able to supply a voltage, and to the battery, on the other hand, the electrical network comprising at least two electrical connection terminals, said circuit being able to convert the voltage supplied by the electrical network into a DC voltage in order to charge the battery, the first midpoint being electrically connected to a first connection terminal of the electrical network, the second midpoint being electrically connected to a second connection terminal of the electrical network.

Advantageously, said circuit is bidirectional and is intended to be connected between the battery and an item of electrical equipment, the circuit being configured to convert the voltage supplied by the battery into an AC voltage able to supply power to said item of electrical equipment.

The invention also relates to an electrical system for a motor vehicle, comprising a circuit as presented above, and a microcontroller able to drive each switch of the circuit to close and open.

By way of example, the circuit is a correction circuit that forms part of a charger, more commonly referred to as an OBC (on-board charger).

The invention also relates to a motor vehicle comprising at least one battery and at least one electrical system as presented above.

The invention also relates to a method for controlling a circuit for a motor vehicle as claimed in the preceding claim, implemented by the microcontroller, when it is necessary to drive two switches connected in parallel to close, said method being noteworthy in that it comprises a first “switching” phase, comprising:
a. a first step of closing a first switch out of the two switches,
b. after a predefined period with respect to the closure of the first switch, a second step of closing the switch connected in parallel with the closed first switch,
c. after a predefined duration after the second closure step, a first step of opening the closed first switch,
d. after a predefined period with respect to the opening of the first switch, a second step of opening the switch connected in parallel with the open first switch.

Thus, during the first switching phase, the fact that one of the switches connected in parallel is already closed when the second switch closes makes it possible for the closed second switch not to undergo any switching losses. Similarly, during the first step of opening a switch, since the other switch is still closed, the switch that opens will not undergo any losses.

More preferably, the method comprises, after the first switching phase, a second “switching” phase, comprising:
a. a first step of closing the switch closed during the second closure step of the first phase,
b. after a predefined period with respect to the closure of the switch during the second phase, a second step of closing the switch closed during the first closure step of the first phase,
c. after a predefined duration after the second closure step of the second phase, a first step of opening the switch closed during the first closure step of the second phase,
d. after a predefined period with respect to the opening of the switch during the second phase, a second step of opening the switch closed during the second closure step of the second phase.

Therefore, during the second switching phase, the switch closed first during the first phase is closed second and the switch closed second during the first phase is closed first. The same applies to the opening of the switches.

The first phase and the second phase therefore make it possible to prevent some of the switching losses for each of the switches.

Preferably, the first phase and the second phase are each iterated an identical number of times. The switching losses are therefore distributed evenly between each of the switches in parallel.

According to a first embodiment, the first phase and the second phase are iterated successively one after the other.

According to a second embodiment, the first phase is reiterated N times in succession, N denoting a positive natural number, then the second phase is iterated N times in succession.

Advantageously, the period is predefined by a duration of between 50 and 100 ns.

The invention also relates to a computer program product characterized in that it comprises a set of program code instructions that, when executed by one or more processors, configure the one or more processors to implement a method as presented above.

### DESCRIPTION OF THE DRAWINGS

Further features and advantages of the invention will become more clearly apparent upon reading the following description. This description is purely illustrative and should be read with reference to the appended drawings, in which:

FIG. 1 is an illustration of a charger according to the invention,

FIG. 2 shows an electronic diagram of a power factor correction circuit of a charger according to FIG. 1,

FIG. 3 shows an electronic diagram of a second embodiment of a power factor correction circuit of a charger according to FIG. 1,

FIG. 4 shows the variation, as a function of time, in the open and closed states of a set of switches of the correction circuit according to either of FIGS. 2 and 3,

FIG. 5 shows an illustration of the method according to the invention.

### DESCRIPTION OF THE EMBODIMENTS

### Vehicle

An embodiment of the invention in the event of it being installed in a vehicle will now be presented. According to this embodiment, the vehicle is an electric or hybrid vehicle and in particular comprises an electric machine that is able to convert electrical energy into mechanical energy in order to rotate the wheels of the vehicle. The electric machine therefore corresponds to the electric propulsion motor of the vehicle.

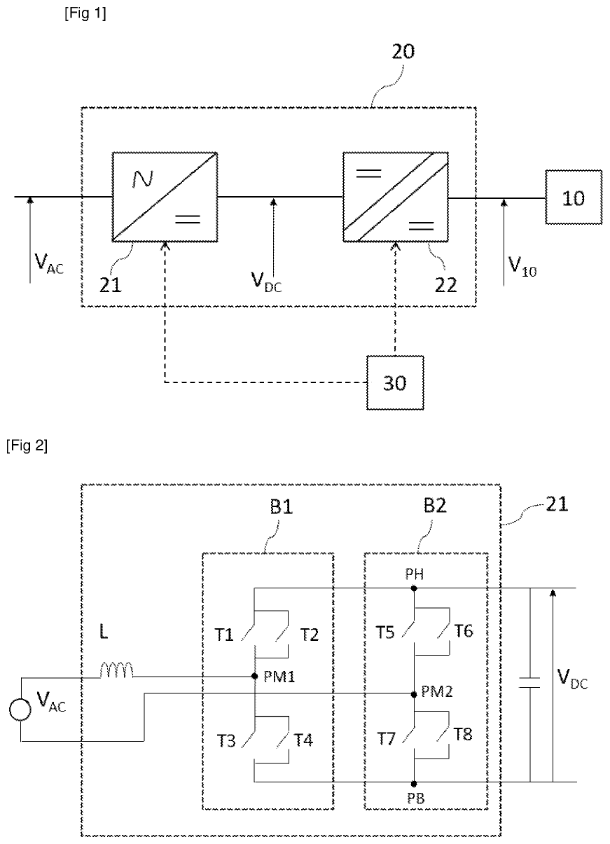

With reference to FIG. 1, the vehicle also comprises a supply battery 10 and an electrical system comprising an on-board charger 20 and a microcontroller 30.

### Battery 10

The electrical supply battery 10 is in particular able to operate in a discharge mode, in which the battery 10 supplies energy to equipment installed in the vehicle or to other equipment external to the vehicles that could be connected to the battery 10 or to the electric machine.

The battery 10 is also able to operate in a charge mode, in which the battery 10 is able to charge from the electrical energy supplied by an electrical network electrically connected to the battery 10.

By way of example, the voltage of the battery 10 may be defined as being between 400 V or 800 V

### Charger 20

The charger 20, better known as an OBC (on-board charger), is connected to the battery 10, on the one hand, and to at least one item of equipment that is installed in the vehicle or external to the vehicle, or to an electrical network that is able to supply an AC voltage, on the other hand.

The charger 20 is termed “bidirectional”. Indeed, when the charger 20 is connected to an electrical network and the battery 10 is operating in the charge state, the charger 20 is in particular able to convert the AC voltage supplied by the electrical network into a DC voltage that is able to charge the battery 10. Moreover, when an item of electrical equipment is connected to the charger 20, the battery 10 operates in the discharge state, the charger 20 being able to convert the DC voltage supplied by the battery 10 into an AC voltage able to supply power to the item of equipment.

More specifically, the charger 20 comprises a power factor correction circuit 21 and a DC-DC voltage converter 22. The converter 22 is electrically connected to the correction circuit 21 via a wired link.

Furthermore, the converter 22 is suited to being electrically connected to the battery 10 and the power factor correction circuit 21 is suited to being electrically connected to an item of equipment of the vehicle or external to the vehicle or to an electrical network.

### Correction Circuit 21

Still with reference to FIG. 1, the power factor correction circuit 21 is able to convert an AC voltage V_{AC} into a DC voltage V_{DC}, and vice versa.

### Converter 22

The DC-DC voltage converter 22 is able to convert a DC voltage V_{DC} into another DC voltage V₁₀.

In particular, the correction circuit 21 and the converter 22 are each able to operate in a “boost” mode, in which the correction circuit 21 and the converter 22 convert a voltage into another DC voltage of higher value.

By way of example, when the battery 10 is operating in the charge mode, the correction circuit 21 is connected to an electrical network. Therefore, the correction circuit 21 converts the AC voltage V_{AC} supplied by the electrical network into a DC voltage V_{DC} defined as being substantially 400 V. Finally, the converter 22 converts the DC voltage V_{DC} into a DC voltage V₁₀ suited to recharging the battery 10, for example a DC voltage of between 220 V and 465 V.

Conversely, when the battery 10 is operating in the discharge mode, then this means that the correction circuit 21 is connected to an item of electronic equipment to be supplied with power. The converter 22 converts the DC voltage V₁₀ supplied by the battery 10 into another DC voltage V_{DC}, for example approximately equal to 400 V. Finally, the correction circuit 21 converts the DC voltage V_{DC} defined as being substantially 400 V into an AC voltage V_{AC} able to supply electrical energy to the item of equipment connected to said correction circuit 21.

With reference to FIG. 2, the detailed electronic structure of the correction circuit 21 if the current characterizing the electrical network or the item of electrical equipment connected to the charger 20 is single-phase will now be presented. The electrical network or the item of equipment therefore comprises two connection terminals, including one phase and one neutral connection terminal.

The correction circuit 21 comprises a coil L, which is necessary for the operation of the boost mode of the correction circuit 21, a first branch B1 and a second branch B2.

The coil L is electrically connected to a first connection terminal of an electrical network or an item of electrical equipment external to the vehicle. The first connection terminal may be the phase or the neutral.

The first branch B1 comprises a first set of switches and a second set of switches. Each set of switches comprises at least two switches connected in parallel. In order to simplify the description, the first and the second set of switches each comprise two switches connected in parallel. Therefore, the first set comprises a first switch T1 and a second switch T2, which are connected in parallel between a high point PH and a first midpoint PM1. The second set comprises a third switch T3 and a fourth switch T4, which are connected in parallel between a low point PB and the first midpoint PM1. The first midpoint PM1 is electrically connected to a first connection terminal of the electrical network or of the item of electrical equipment connected to the charger 20 via the coil L.

The correction circuit 21 also comprises a second branch B2, the structure of which is similar to that of the first branch B1. Therefore, the second branch B2 comprises a fifth switch T5 and at least a sixth switch T6, which are connected in parallel between the high point PH and a second midpoint PM2, the second branch B2 comprising a seventh switch T7 and at least an eighth switch T8, which are connected in parallel between the low point PB and the second midpoint PM2. The second midpoint PM2 is electrically connected to a second connection terminal of the electrical network or of the item of electrical equipment connected to the charger 20. The second branch B2 may also comprise, for each set of switches in parallel, more than two switches in parallel.

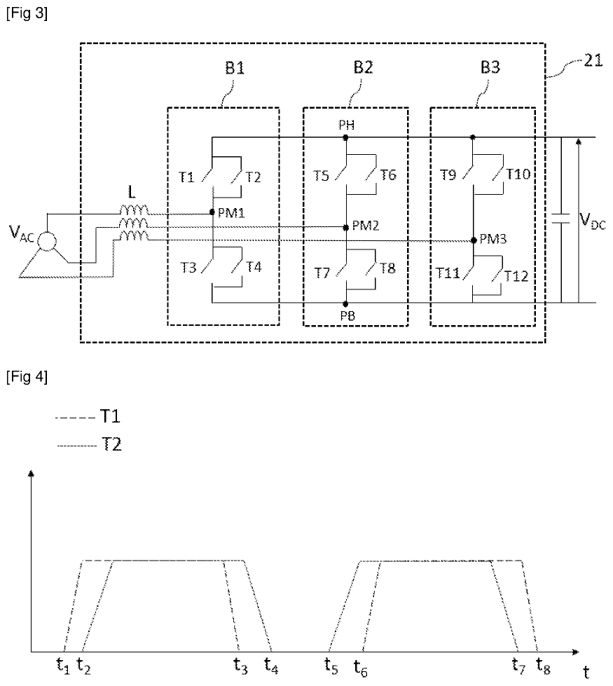

With reference to FIG. 3, the detailed electronic structure of the correction circuit 21 if the current characterizing the electrical network or the item of electrical equipment connected to the charger 20 is three-phase will now be presented. The electrical network or the item of electrical equipment therefore comprises three connection terminals and the correction circuit 21 comprises a third branch B3.

Similarly, the third branch B3 comprises a structure similar to that of the first branch B1. The third branch B3 therefore comprises a ninth switch T9 and at least a tenth switch T10, which are connected in parallel between the high point PH and a third midpoint PM3, the third branch B3 comprising an eleventh switch T11 and at least a twelfth switch T12, which are connected in parallel between the low point PB and the third midpoint PM3. The third midpoint PM3 is electrically connected to the third connection terminal of the electrical network or of the item of equipment. The third branch B3 may also comprise, for each set of switches in parallel, more than two switches in parallel.

Therefore, each of the branches B1, B2, B3 comprises switches in parallel, therefore allowing the switching losses to be distributed between each of the two switches in parallel.

The first branch B1, the second branch B2 and the third branch B3 each constitute an electronic half-bridge.

The high point PH is, for example, connected to a DC voltage of between 250 V and 850 V, and the low point PB is, for example, connected to ground.

### Microcontroller 30

The microcontroller 30 is able to drive each switch T1, T2, T3, T4, T5, T6, T7, T8, T9, T10, T11, T12 of the correction circuit 21 to open and close. To this end, the microcontroller 30 is able to transmit, to each switch, a control signal that is able to vary the duty cycle of the opening and closing switching frequency of each switch.

The microcontroller 30 has a processor that is able to implement a set of instructions allowing these functions to be performed.

### Method

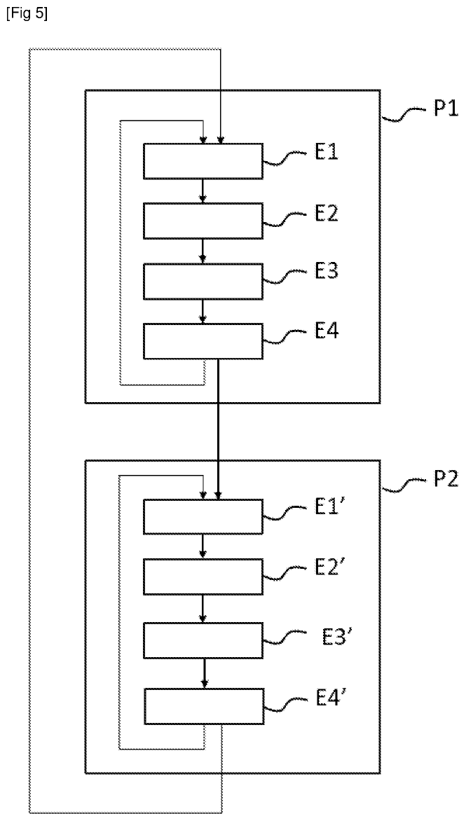

With reference to FIGS. 4 and 5, an embodiment of the method, which is implemented by the microcontroller 30, will now be presented.

The method is described here in the event of it being necessary to drive the first switch T1 and the second switch T2, which are connected in parallel, to close; however, the method as described below may also be applied to any set of at least two switches connected in parallel in the correction circuit 21. In order to simplify the description, the method will be described for a set of two switches.

### First Switching Phase P1

The method comprises a first “switching” phase P1.

According to a first embodiment, the first phase P1 comprises a first step E1 of closing one switch out of the two switches in parallel. By way of example, the microcontroller 30 transmits a first closure control signal to the first switch T1 at a first time t₁. The first switch T1 closes, thus allowing the midpoint PM1 to be connected to the high point PH.

After a duration equal to a first predefined period from the transmission of the first closure control signal for the first switch T1, the first phase P1 comprises a second step E2 of closing the switch connected in parallel with the switch closed during the first closure step E1. In other words, according to the first embodiment, the second closure step E2 involves the second switch T2 connected in parallel with the first switch T1 closing, which entails the microcontroller 30 transmitting a second closure control signal to the second switch T2 at a second time t₂. Therefore, since the first midpoint PM1 was set to the voltage defined at the high point PH when the first switch T1 closed previously, the second switch T2 does not undergo any switching losses when it closes.

When the first branch B1 comprises, for each set of switches, more than two switches connected in parallel, when the first switch T1 is closed and the first midpoint PM1 is connected to the voltage defined at the high point PH, none of the switches connected in parallel with the closed first switch T1 undergoes any switching losses when each of said switches in parallel is closed.

The first phase P1 then comprises a first step E3 of opening the switch closed during the first closure step E1, and therefore the first switch T1, in which the microcontroller 30 transmits a first opening control signal to the first switch T1 at a third time t₃. As the second switch T2 is still closed when the first switch T1 opens, the voltage at the first midpoint PM1 is still equal to the voltage defined at the high point PH and the first switch T1 does not undergo any switching losses.

When the first branch B1 comprises, for each set of switches, more than two switches connected in parallel, when the second switch T2 is closed and the first midpoint PM1 is connected to the voltage defined at the high point PH, none of the switches connected in parallel with the closed second switch T2 undergoes any switching losses when each of said switches in parallel is open.

After a second predefined period from the transmission of the first opening control signal, the first phase P1 comprises a second step E4 of opening the second switch T2, in which the microcontroller 30 transmits a second opening control signal to the second switch T2 at a fourth time t₄.

### Second Switching Phase P2

The method also comprises a second “switching” phase P2, which, for example, occurs after the first phase P1.

The second phase P2 comprises a first step E1′ of closing one switch out of the two switches in parallel. However, during the first closure step E1′ of the second phase P2, it is the switch that was closed second during the first phase P1 that is closed first. Therefore, the microcontroller 30 transmits a first closure control signal to the second switch T2 at a fifth time t₅. The second switch T2 closes, thus allowing the midpoint PM1 to be connected to the high point PH.

After a duration equal to a third predefined period from the transmission of the first closure control signal for the second switch T2 of the second phase P2, the method comprises a second step E2′ of closing the first switch T1 connected in parallel with the already closed second switch T2, in which the microcontroller 30 transmits a second closure control signal to the first switch T1 at a sixth time t₆. Therefore, since the first midpoint PM1 was set to the voltage defined at the high point PH when the second switch T2 closed, the first switch T1 does not undergo any switching losses when it closes. To be precise, when each set of switches comprises more than two switches in parallel, when the second switch T2 has closed previously, this means that none of the other switches connected in parallel with the closed second switch T2 will undergo any switching losses when they close.

The second phase P2 then comprises a first step E3′ of opening the switch closed during the first closure step E1′ of the second phase P2, and therefore the second switch T2, in which the microcontroller 30 transmits a first opening control signal to the second switch T2 at a seventh time t₇. As the first switch T1 is still closed when the second switch T2 opens, the voltage at the first midpoint PM1 is still equal to the voltage defined at the high point PH and the second switch T2 does not undergo any switching losses when it opens. To be precise, when each set of switches comprises more than two switches in parallel, when the first switch T1 has closed previously, this means that none of the other switches connected in parallel with the closed first switch T1 will undergo any switching losses when they open.

After a fourth predefined period from the transmission of the first opening control signal of the second phase P2, the second phase P2 comprises a second step E4′ of opening the first switch T1, in which the microcontroller 30 transmits a second opening control signal to the first switch T1.

The first phase P1 is reiterated as many times as the second phase P2. Preferably, the first phase P1 and the second phase P2 are reiterated alternately, in other words they are implemented one after the other. According to a second embodiment, the first phase P1 is reiterated N times in succession, N denoting a positive natural number, then the second phase P2 is iterated N times in succession.

Each predefined period corresponds to a duration with a value of between 50 ns and 100 ns. More precisely, each period value depends on the duration for which each switch is open and closed.

The method may likewise be implemented for the second set of switches, in other words for the third switch T3 and the fourth switch T4. However, in the present case, when one of the switches is closed, this allows the midpoint PM1 to be connected to the low point PB, in other words to ground. This has the same effect as connecting the midpoint PM1 to the high point PH; in other words this allows the switching losses to be reduced by applying a DC voltage value to the midpoint PM1.

The losses are therefore distributed evenly between each of the switches in parallel rather than to just one switch. The service life of each switch is therefore prolonged.

The control method has been described here in the case of control of switches in parallel in a first branch B1 of a correction circuit 21 of a vehicle on-board charger 20, but the method may also be applied to any half-bridge (comprising switches connected in parallel) installed in an electric, hybrid or combustion-engine vehicle.

1. An electronic circuit (21) for a motor vehicle, comprising a first branch (B1) comprising a first switch (T1) and at least a second switch (T2), which are connected in parallel between a high point (PH) and a first midpoint (PM1), the first branch (B1) comprising a third switch (T3) and at least a fourth switch (T4), which are connected in parallel between a low point (PB) and the first midpoint (PM1).

2. The circuit (21) as claimed in claim 1, comprising a second branch (B2) comprising a fifth switch (T5) and at least a sixth switch (T6), which are connected in parallel between the high point (PH) and a second midpoint (PM2), the second branch (B2) comprising a seventh switch (T7) and at least an eighth switch (T8), which are connected in parallel between the low point (PB) and the second midpoint (PM2).

3. The circuit (21) as claimed in claim 1, in which each switch (T1, T2, T3, T4) is a transistor.

4. The circuit (21) as claimed in claim 1, the vehicle comprising at least one supply battery (10), the circuit (21) being intended to be connected to an electrical network, on the one hand, which is external to the vehicle and able to supply a voltage, and to the battery (10), on the other hand, the electrical network comprising at least two electrical connection terminals, said circuit (21) being able to convert the voltage supplied by the electrical network into a DC voltage in order to charge the battery (10), the first midpoint (PM1) being electrically connected to a first connection terminal of the electrical network, the second midpoint (PM2) being electrically connected to a second connection terminal of the electrical network.

5. The circuit (21) as claimed in claim 4, said circuit (21) being bidirectional and being intended to be connected between the battery (10) and an item of electrical equipment, the circuit (21) being configured to convert the voltage supplied by the battery (10) into an AC voltage able to supply power to said item of electrical equipment.

6. An electrical system for a motor vehicle, said system comprising a circuit (21) as claimed in claim 1, and a microcontroller (30) able to drive each switch (T1, T2, T3, T4, T5, T6, T7, T8, T9, T10, T11, T12) of the circuit (21) to close and open.

7. A motor vehicle comprising at least one battery (10) and at least one electrical system as claimed in claim 6.

8. A method for controlling a circuit (21) for a motor vehicle as claimed in claim 7, implemented by the microcontroller (30) when it is necessary to drive two switches (T1, T2) connected in parallel to close, said method being characterized in that it comprises a first “switching” phase (P1), comprising:
a. a first step (E1) of closing a first switch (T1, T2) out of the two switches (T1, T2),
b. after a predefined period with respect to the closure of the first switch (T1), a second step (E2) of closing the switch (T2) connected in parallel with the closed first switch (T1),
c. after a predefined duration after the second closure step (E2), a first step (E3) of opening the closed first switch (T1),
d. after a predefined period with respect to the opening of the first switch (T1), a second step (E4) of opening the switch (T2) connected in parallel with the open first switch (T1).

9. The method as claimed in claim 8, comprising, after the first switching phase (P1), a second “switching” phase (P2), comprising:
a. a first step (E1′) of closing the switch closed during the second closure step (E2) of the first phase (P1),
b. after a predefined period with respect to the closure (E1′) of the switch during the second phase (P2), a second step (E2′) of closing the switch closed during the first closure step (E1) of the first phase (P1),
c. after a predefined duration after the second closure step (E2′) of the second phase (P2), a first step (E3′) of opening the switch closed during the first closure step (E1′) of the second phase (P2),
d. after a predefined period with respect to the opening (E3′) of the switch during the second phase (P2), a second step (E4) of opening the switch closed during the second closure step (E2′) of the second phase (P2).

10. The method as claimed in claim 7, in which the period is predefined by a duration of between 50 and 100 ns.
